(19) United States
(12) Patent Application Publication
(10) Pub. No.: US 2007/0045727 A1
(43) Pub. Date: Mar. 1, 2007

(54) DMOSFET and planar type MOSFET

(76) Inventors: Masaki Shiraishi, Hitachinaka (JP); Takayuki Iwasaki, Tokai (JP); Nobuyoshi Matsuura, Takasaki (JP); Yoshito Nakazawa, Takasaki (JP); Tsuyoshi Kachi, Takasaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/508,860

(22) Filed: Aug. 24, 2006

(30) Foreign Application Priority Data
Aug. 25, 2005 (JP) JP2005-243547

(51) Int. Cl. H01L 29/76

(52) U.S. Cl. 257/335

(57) ABSTRACT

A technology capable of realizing a MOSFET with low ON-resistance and low feedback capacitance, in which the punch through of a channel layer can be prevented even when the shallow junction of the channel layer is formed in a planar type MOSFET is provided. A P type polysilicon is used for a gate electrode in a planar type MOSFET, in particular, in an N channel DMOSFET.

### CROSS-REFERENCE TO RELATED APPLICATION

The present application claims priority from Japanese Patent Application No. JP 2005-243547 filed on Aug. 25, 2005, the content of which is hereby incorporated by reference into this application.

### TECHNICAL FIELD OF THE INVENTION

The present invention relates to a power MOSFET (Metal Oxide Semiconductor Field Effect Transistor). More particularly, it relates to a technology effectively applied to a structure and its manufacturing method suitable for achieving low ON-resistance and low feedback capacitance in a low withstand voltage power MOSFET with the withstand voltage of 100 V or lower and a power supply device using the power MOSFET.

### BACKGROUND OF THE INVENTION

For example, current and frequency of a non-insulated DC/DC converter used in a power supply device of a desktop PC, a note PC, a game machine and others have been increasing due to the demands for higher current for CPU (Central Processing Unit) and MPU (Micro Processing Unit) to be driven and size reduction of passive components such as choke coil and input/output capacitor. The DC/DC converter is composed of a high-side switch and a low-side switch, and power MOSFETs are used for these switched.

These high-side and low-side switches are alternately turned on and off in synchronization with each other to perform voltage conversion. The high-side switch is a switch for controlling the DC/DC converter and the low-side switch is a switch for synchronous rectification.

The main loss in the high-side switch is the switching loss caused in the switching operation, and the power MOSFET used for the high-side switch is required to reduce its ON-resistance (Ron) and feedback capacitance (Crss). Further, the main loss in the low-side switch is the conduction loss, and the power MOSFET used for the low-side switch is required to reduce its ON-resistance (Ron).

Also, the DC/DC converter described above has the problem of self turn-on phenomenon. The self turn-on is the phenomenon as follows. That is, when a high-side switch is turned on while a low-side switch is in an OFF state, drain voltage of the low-side switch is increased, and charging current flows due to the voltage change between the gate and the source of the low-side switch via the feedback capacitance between the gate and the drain of the low-side switch. Accordingly, the gate voltage of the low-side switch is increased, and when it reaches the threshold voltage, the false firing of the low-side switch occurs. When the self turn-on occurs, the large through current flows from the high-side switch to the low-side switch and the conversion efficiency is significantly lowered. Since the increase of the gate voltage of the low-side switch is proportional to the ratio between the feedback capacitance and the input capacitance (Crss/Ciss) of the low-side switch, the low-side switch is also required to reduce its Crss/Ciss in addition to the ON-resistance.

In the current DC/DC converter, the operating frequency is not so high and is about 300 kHz. Therefore, the power MOSFETs with a trench structure are mainly used for both the high-side switch and the low-side switch. The use of the trench power MOSFET can reduce the cell size and can achieve the low ON-resistance because JFET (Junction Field Effect Transistor) resistance is not generated. However, since the feedback capacitance is high in the trench power MOSFET, the switching loss and the loss due to the self turn-on are increased as the frequency of the DC/DC converter is increased.

As a power MOSFET capable of reducing the feedback capacitance, a planar type MOSFET is known. However, since the JFET resistance is present in the planar type MOSFET, it is difficult to reduce the cell size and thus difficult to reduce the ON-resistance.

For example, Japanese Patent Application Laid-Open Publication No. 2003-298052 (Patent Document 1) has proposed a structure where an N type region with higher concentration than a drift layer is provided in a JFET region between channels of planar type MOSFETs. By this means, since the JFET region can be narrowed, the cell size can be reduced and the low ON-resistance can be achieved.

### SUMMARY OF THE INVENTION

However, in the planar type MOSFET of the Patent Document 1, the miniaturization of the cell is insufficient, and the ON-resistance is still high in comparison to the trench MOSFET and the examination for further reduction of the ON-resistance is necessary. Also, it is known that the reduction of the ON-resistance without being affected by the JFET resistance can be achieved in the planar type MOSFET by forming the shallow junction of the channel layer. However, in the planar type MOSFET of the Patent Document 1, the depth of the channel layer is about 0.8 Mm, and the examination for the shallow junction is insufficient. Furthermore, when the shallow junction of the channel layer is formed, diffusion in a lateral direction of the channel is also decreased. Therefore, the planar type MOSFET has a problem in its structure that the punch through of the channel layer occurs and the withstand voltage is decreased. Therefore, the planar type MOSFET having a shallow channel layer with a channel depth of 0.5 μm or less has not been examined.

Accordingly, an object of the present invention is to provide a technology capable of realizing a MOSFET with low ON-resistance and low feedback capacitance, in which the punch through of a channel layer is prevented even when the shallow junction of the channel layer is formed in a planar type MOSFET.

The above and other objects and novel characteristics of the present invention will be apparent from the description of this specification and the accompanying drawings.

The typical ones of the inventions disclosed in this application will be briefly described as follows.

The feature of the present invention lies in that, in a planar type MOSFET, shallow junction of a channel layer with a channel depth of 0.5 μm or less is formed in order to achieve the low ON-resistance and the low feedback capacitance, and the present invention has features as follows in order to prevent the punch through of a channel layer in which the diffusion in a lateral direction is decreased due to the shallow junction.

(1) A P type polysilicon electrode is used for a gate electrode in an N channel DMOSFET (Double-Diffused MOSFET).

(2) A shallow N type layer like an LDD (Lightly Doped Drain) region is provided in a source region so that the source region has a two-stage structure.

The effects obtained by typical aspects of the present invention will be briefly described below.

According to the present invention, in a planar type MOSFET, since the punch through of a channel layer can be prevented even when a shallow junction of a channel layer is formed, it is possible to realize a MOSFET with low ON-resistance and low feedback capacitance.

Further, according to the present invention, since the planar type MOSFET described above is used for a high-side switch and a low-side switch of a DC/DC converter, the loss in the system can be reduced.

### BRIEF DESCRIPTIONS OF THE DRAWINGS

FIG. 1 is a diagram showing a sectional structure of a planar type MOSFET according to the first embodiment of the present invention;

FIG. 2 is a cross-sectional view showing the dimensions of the planar type MOSFET according to the first embodiment of the present invention;

FIG. 3A is a diagram showing a difference in energy band of a gate electrode, a gate insulating film, and a channel layer in a thermal equilibrium state due to the difference in polarity of the polysilicon of the gate electrode according to the first embodiment of the present invention;

FIG. 3B is a diagram showing a difference in energy band of a gate electrode, a gate insulating film, and a channel layer in a thermal equilibrium state due to the difference in polarity of the polysilicon of the gate electrode according to the first embodiment of the present invention;

FIG. 4 is a graph showing the calculation result of impurity concentration distribution in a cross section taken along the line A-A′ in FIG. 1 and hole concentration distributions at the time of Vds=0 V in the case where the N type polysilicon and the P type polysilicon are used for the gate electrode according to the first embodiment of the present invention;

FIG. 5 is a graph showing the calculation result of the withstand voltage between drain and source based on the difference in polarity of the polysilicon used for the gate electrode according to the first embodiment of the present invention;

FIG. 6A is a diagram showing the two-dimensional distribution of equipotential lines at the time when the voltage of 20 V is applied between drain and source based on the difference in polarity of polysilicon used for the gate electrode according to the first embodiment of the present invention;

FIG. 6B is a diagram showing the two-dimensional distribution of equipotential lines at the time when the voltage of 20 V is applied between drain and source based on the difference in polarity of polysilicon used for the gate electrode according to the first embodiment of the present invention;

FIG. 7 is a graph showing the calculation result of the length of JFET region and the ON-resistance per unit area according to the first embodiment of the present invention;

FIG. 8A is a cross-sectional view showing a manufacturing method of the planar type MOSFET according to the first embodiment of the present invention;

FIG. 8B is a cross-sectional view showing the manufacturing method of the planar type MOSFET according to the first embodiment of the present invention;

FIG. 8C is a cross-sectional view showing the manufacturing method of the planar type MOSFET according to the first embodiment of the present invention;

FIG. 9D is a cross-sectional view showing the manufacturing method of the planar type MOSFET according to the first embodiment of the present invention;

FIG. 9E is a cross-sectional view showing the manufacturing method of the planar type MOSFET according to the first embodiment of the present invention;

FIG. 9F is a cross-sectional view showing the manufacturing method of the planar type MOSFET according to the first embodiment of the present invention;

FIG. 10G is a cross-sectional view showing the manufacturing method of the planar type MOSFET according to the first embodiment of the present invention;

FIG. 10H is a cross-sectional view showing the manufacturing method of the planar type MOSFET according to the first embodiment of the present invention;

FIG. 10I is a cross-sectional view showing the manufacturing method of the planar type MOSFET according to the first embodiment of the present invention;

FIG. 11J is a cross-sectional view showing the manufacturing method of the planar type MOSFET according to the first embodiment of the present invention;

FIG. 11K is a cross-sectional view showing the manufacturing method of the planar type MOSFET according to the first embodiment of the present invention;

FIG. 11L is a cross-sectional view showing the manufacturing method of the planar type MOSFET according to the first embodiment of the present invention;

FIG. 12M is a cross-sectional view showing the manufacturing method of the planar type MOSFET according to the first embodiment of the present invention;

FIG. 12N is a cross-sectional view showing the manufacturing method of the planar type MOSFET according to the first embodiment of the present invention;

FIG. 13 is a diagram showing a cross-sectional structure of a planar type MOSFET according to the second embodiment of the present invention;

FIG. 14 is a diagram showing a cross-sectional structure of a planar type MOSFET according to the third embodiment of the present invention;

FIG. 15 is a diagram showing a cross-sectional structure of a planar type MOSFET according to the fourth embodiment of the present invention;

FIG. 16 is a diagram showing a cross-sectional structure of a planar type MOSFET according to the fourth embodiment of the present invention;

FIG. 17 is a diagram showing a cross-sectional structure of a planar type MOSFET according to the fifth embodiment of the present invention;

FIG. 18 is a diagram showing a cross-sectional structure of a planar type MOSFET according to the sixth embodiment of the present invention;

FIG. 19 is a diagram showing a cross-sectional structure of a planar type MOSFET according to the seventh embodiment of the present invention;

FIG. 20 is a diagram showing a cross-sectional structure of a planar type MOSFET according to the eighth embodiment of the present invention;

FIG. 21 is a diagram showing a cross-sectional structure of a planar type MOSFET according to the ninth embodiment of the present invention;

FIG. 22 is a graph showing the calculation result of the withstand voltage between drain and source in each structure according to the ninth embodiment of the present invention;

FIG. 23A is a diagram showing the two-dimensional distribution of equipotential lines at the time when the voltage of 20 V is applied between drain and source in the conventional planar type MOSFET;

FIG. 23B is a diagram showing the two-dimensional distribution of equipotential lines at the time when the voltage of 20 V is applied between drain and source in the planar type MOSFET according to the ninth embodiment of the present invention;

FIG. 24 is a diagram showing a circuit configuration of the non-insulated DC/DC converter included in the power supply device according to the tenth embodiment of the present invention;

FIG. 25 is a graph showing the calculation results of the dependence of the feedback capacitance on the drain voltage in the conventional trench MOSFET and the planar type MOSFET of the present invention according to the tenth embodiment of the present invention; and

FIG. 26 is a graph showing the calculation results of the gate voltage of the low-side switch in the case where the conventional trench MOSFET is used for the low-side switch of the DC/DC converter and the case where the planar type MOSFET of the present invention is used for the low-side switch of the DC/DC converter.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

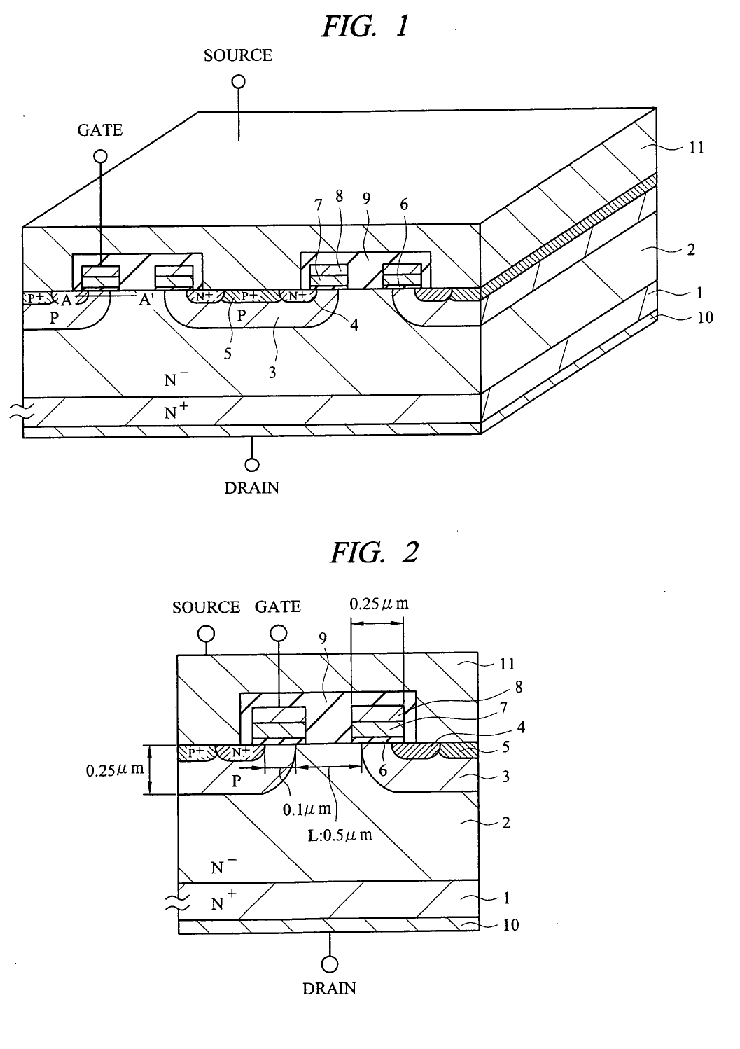

The first embodiment of the present invention will be described with reference to FIG. 1 to FIG. 8. FIG. 1 is a diagram showing a sectional structure of a planar type MOSFET according to the first embodiment of the present invention. FIG. 2 is a cross-sectional view showing the dimensions of the planar type MOSFET according to the first embodiment of the present invention.

As shown in FIG. 1, the planar type MOSFET according to the first embodiment is a planar type N channel DMOSFET (Double-Diffused MOSFET), in which an N⁻ epitaxial layer 2 is formed on an N⁺ substrate 1, and P channel layers 3, N⁺ source regions 4, and body contact regions 5 are formed in this N⁻ epitaxial layer 2, and P type polysilicons 7 to be gate electrodes are formed thereon via gate insulating films 6. A part of the P type polysilicon 7 opposite to the JFET region between the P channel layers 3 is removed, and a tungsten silicide film 8 is formed on the P type polysilicon 7. The upper and side surfaces of the tungsten silicide film and the side surfaces of the P type polysilicon 7 are covered with an insulating film 9. In this DMOSFET, a source electrode 11 is provided on a front surface and a drain electrode 10 is provided on a rear surface, respectively. Note that, although the gate electrodes are arranged in a stripe pattern in the structure shown in FIG. 1, the gate electrodes can be arranged in a mesh pattern of polygonal shapes and ladder shapes.

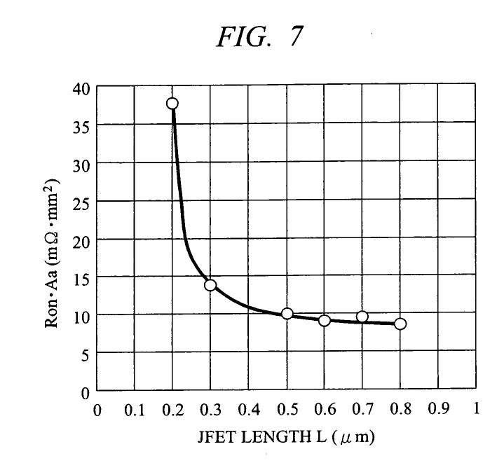

The feature of this embodiment lies in that the junction depth of the P channel layer 3 is as shallow as 0.25 μm as shown in FIG. 2. Accordingly, the JFET region between channel layers can be narrowed (it is narrowed to 0.5 μm in FIG. 2). As a result, the cell pitch can be reduced, and the ON-resistance can be reduced. FIG. 7 is a graph showing the calculation result of the length of JFET region (L) and the ON-resistance per unit area (Ron·Aa). As is apparent from FIG. 7, when the length L is narrowed to 0.5 μm or less, the JFET resistance is increased and the total ON-resistance starts to increase. Therefore, the length L is not narrowed to less than 0.5 μm.

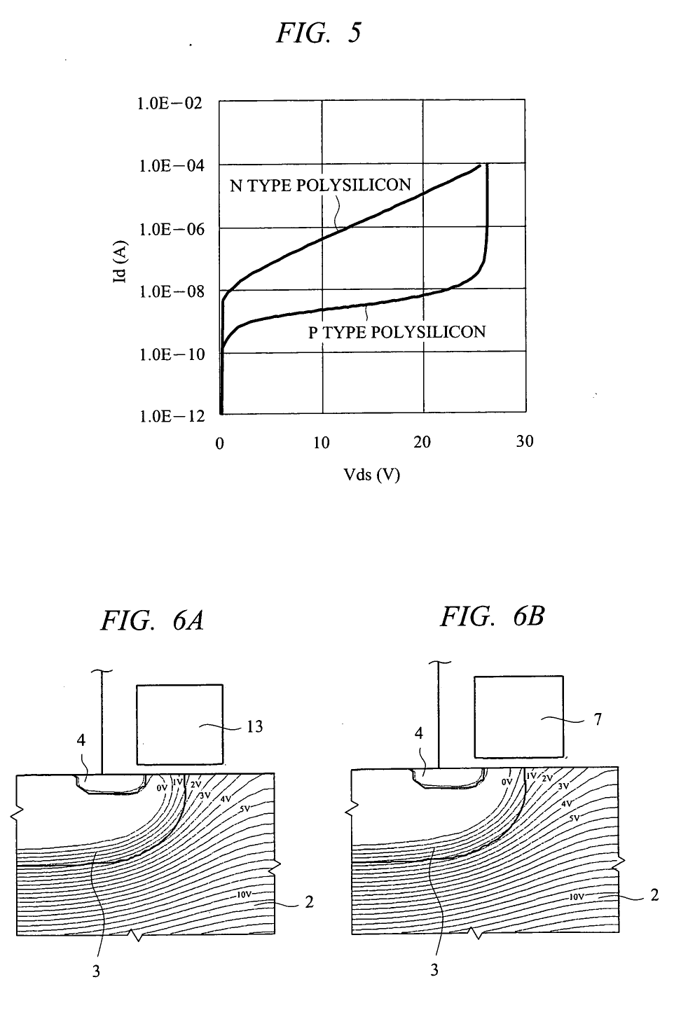

In this embodiment, since the P channel layer 3 is shallowly formed, the diffusion in a lateral direction is also small, and the channel length in FIG. 2 is as small as 0.1 μm. Therefore, if a gate electrode of N type polysilicon used as a gate electrode of a normal N channel MOSFET is used in this case, the punch through of the channel layer occurs, and the withstand voltage cannot be retained as shown in FIG. 5. In order to prevent the punch through described above, the P type polysilicon 7 is used for the gate electrode, which is the primary feature of this embodiment. FIG. 3 to FIG. 6 are explanatory diagrams showing the phenomenon in which the punch through is prevented by using the P type polysilicon 7 for the gate electrode, and the phenomenon will be sequentially described below.

FIG. 3 is a diagram showing a difference in energy band of a gate electrode, a gate insulating film, and a channel layer in a thermal equilibrium state due to the difference in polarity of the polysilicon of the gate electrode, in which FIG. 3A shows an energy band of a gate electrode made of N type polysilicon, a gate insulating film, and a P channel layer in a thermal equilibrium state. The Fermi level of the N type polysilicon is present near the bottom of the conduction band and the band of the P channel layer bends downward on the surface of the gate insulating film in the thermal equilibrium state as shown in FIG. 3A, and the holes of the surface are emitted and the depletion occurs. On the other hand, FIG. 3B shows an energy band in the case where the P type polysilicon 7 is used for the gate electrode. The Fermi level of the P type polysilicon 7 is present near the top of valence band, and the band of the P channel layer 3 hardly bends in the thermal equilibrium state, and the holes of the surface are not emitted.

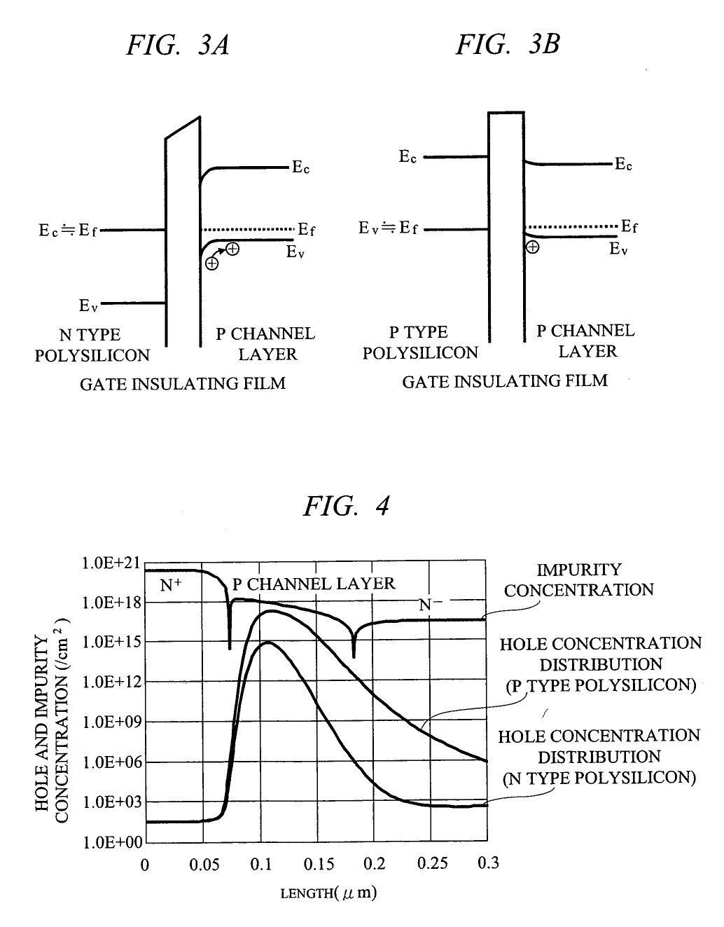

FIG. 4 is a graph showing the calculation result of impurity concentration distribution in a cross section taken along the line A-A′ in FIG. 1 and hole concentration distributions at the time of Vds=0 V in the case where the N type polysilicon and the P type polysilicon are used for the gate electrode. As is apparent from FIG. 4, when the N type polysilicon is used for the gate electrode, the hole concentration of the surface of the P channel layer is decreased. On the other hand, when the P type polysilicon 7 is used for the gate electrode like this embodiment, though the hole concentration is decreased compared with the impurity concentration due to the influence of the built-in potential of the PN junction, the hole concentration of the surface of the P channel layer 3 is two digits higher than that of the case where the N type polysilicon is used for the gate electrode, and the punch through of the channel layer can be prevented.

FIG. 5 is a graph showing the calculation result of the withstand voltage between drain and source based on the difference in polarity of the polysilicon used for the gate electrode. As shown in FIG. 5, when the N type polysilicon is used, the punch through of the channel layer occurs and the leakage current is increased. Meanwhile, when the P type polysilicon 7 is used like in this embodiment, the punch through of the P channel layer 3 can be prevented and the sharp withstand voltage curve can be obtained.

FIG. 6 is a diagram showing the two-dimensional distribution of equipotential lines at the time when the voltage of 20 V is applied between drain and source based on the difference in polarity of polysilicon used for the gate electrode. As is apparent from FIG. 6A, the equipotential lines extend to the N⁺ source region 4 when the N type polysilicon 13 is used, and the punch through of the P channel layer 3 occurs. On the other hand, when the P type polysilicon 7 is used like this embodiment, as shown in FIG. 6B, the equipotential lines do not reach the N⁺ source region 4, and the punch through can be prevented.

As described above, it can be understood from FIG. 3 to FIG. 6 that the punch through of the channel layer due to the shallow junction of the P channel layer 3 can be prevented in this embodiment by using the P type polysilicon 7 for the gate electrode instead of conventionally used N type polysilicon.

Another feature of this embodiment lies in that a part of the gate electrode opposite to the JFET region is removed in order to reduce the input capacitance of the gate and the feedback capacitance between gate and drain. Also, since the size of the gate electrode is as small as 0.25 μm as shown in FIG. 2 in this embodiment, there is the problem that the gate resistance is increased. For its prevention, a tungsten silicide film 8 as a metal film is formed on the gate electrode in this embodiment.

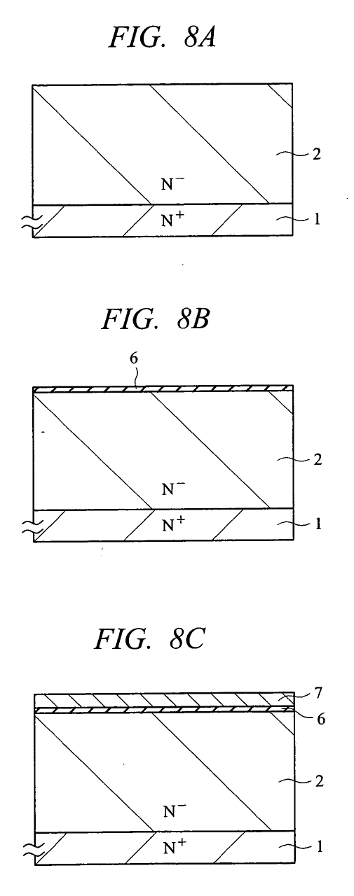

FIG. 8 to FIG. 12 are cross-sectional views showing an example of the manufacturing method of the planar type MOSFET according to this embodiment including the step of forming the tungsten silicide film on the gate electrode.

First, a surface of the N⁻ epitaxial layer 2 on the N⁺ substrate 1 shown in FIG. 8A is oxidized as shown in FIG. 8B to form the gate insulating film 6. Though described later, this gate insulating film 6 may be an oxide film or an oxynitride film formed through the oxidation in a nitrogen atmosphere. Then, as shown in FIG. 8C, the P type polysilicon 7 is deposited. The P type polysilicon 7 can be formed by directly depositing the P type polysilicon 7. Alternatively, after depositing insulating polysilicon, the ion implantation of boron (B) or boron difluoride (BF₂) and thermal diffusion thereof are performed, thereby forming the P type polysilicon 7.

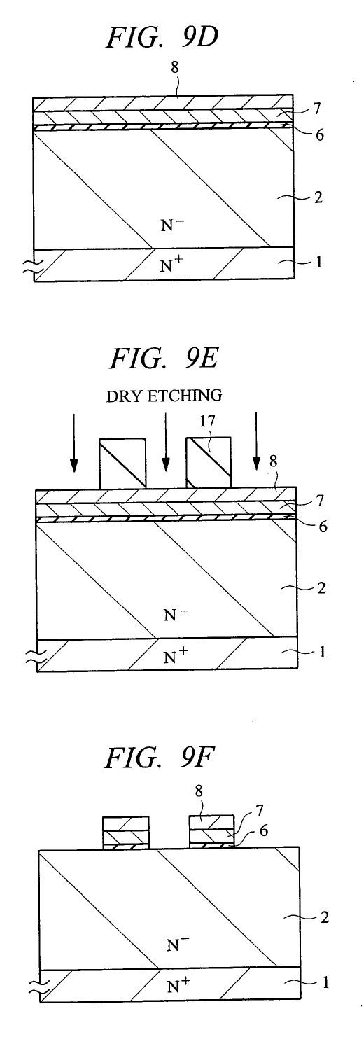

Next, as shown in FIG. 9D, a tungsten silicide film 8 as a metal electrode is deposited. Thereafter, through the photoresist process and the dry etching using a photoresist 17 as a mask as shown in FIG. 9E, gate structures each having the P type polysilicon 7 and the tungsten silicide film 8 laminated on the gate insulating film 6 are formed as shown in FIG. 9F.

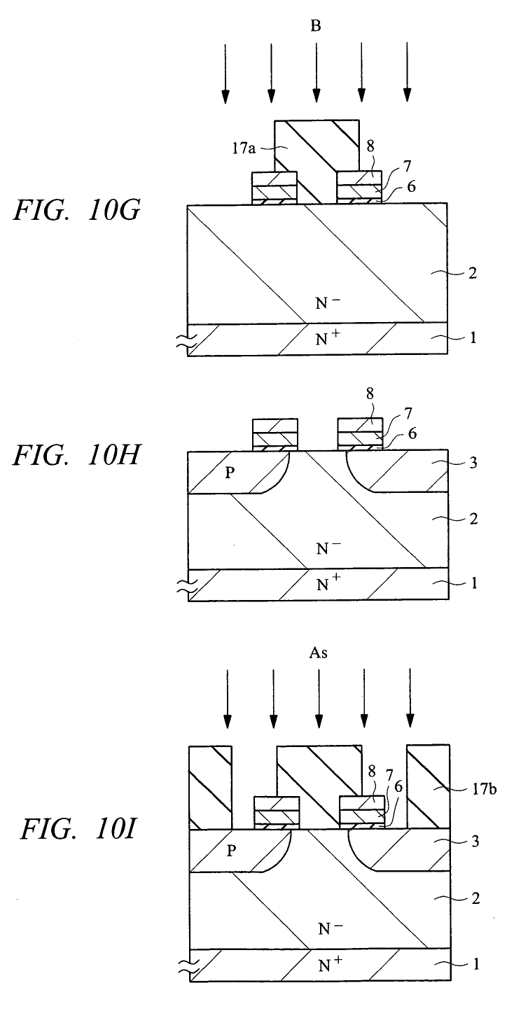

Next, as shown in FIG. 10G, channel photolithography and ion implantation are performed with using a photoresist 17a as a mask. In this step, in the conventional planar type MOSFET, ions are obliquely implanted or oblique ion implantation called pocket implantation is performed after the vertical ion implantation in some cases in order to prevent the punch through. In this embodiment, however, owing to the shallow junction of the P channel layer 3 and the prevention of the punch through by the use of the P type polysilicon 7, the P channel layer 3 can be formed by only the vertical ion implantation of boron (B). More specifically, as shown in FIG. 10H, the P channel layers 3 are formed through the thermal diffusion, and then, source photolithography and ion implantation of arsenic (As) are performed with using a photoresist 17b as a mask as shown in FIG. 10I.

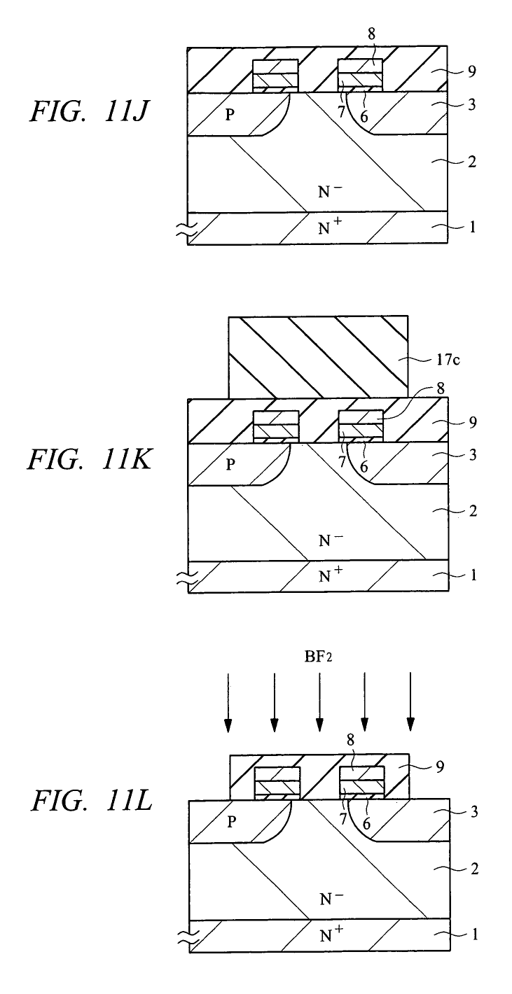

Next, as shown in FIG. 11J, a protective film formed of the insulating film 9 is deposited. Thereafter, as shown in FIG. 11K, photolithography for forming body contact is performed with using a photoresist 17c as a mask. Then, as shown in FIG. 11L, ion implantation of boron difluoride is performed.

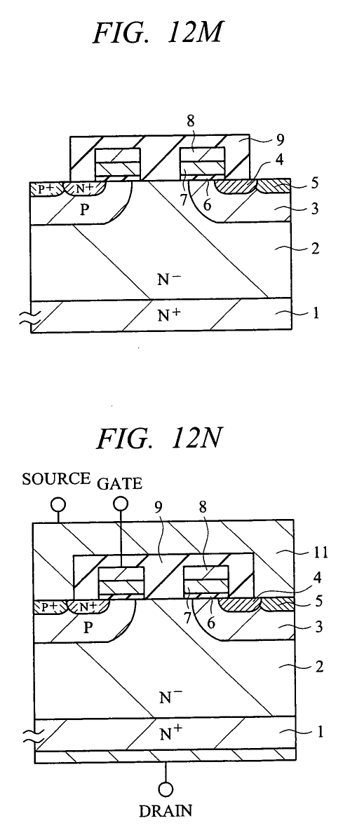

Next, as shown in FIG. 12M, thermal diffusion is performed to form the N⁺ source regions 4 and the body contact regions 5. Finally, as shown in FIG. 12N, the source electrode 11 made of aluminum (Al) is formed on a front surface. Thereafter, a rear surface is polished and gold (Au) or the like is deposited on the rear surface to form the drain electrode 10. Through the process described above, a device of the planar type MOSFET is completed.

The planar type MOSFET according to the first embodiment can be fabricated by the diversion of the CMOSFET process. In particular, in order to perform the process of miniaturized gate electrode and the STI process described in the following embodiments, it is desired to use the CMOSFET process with a design rule of 0.25 μm or less.

### Second Embodiment

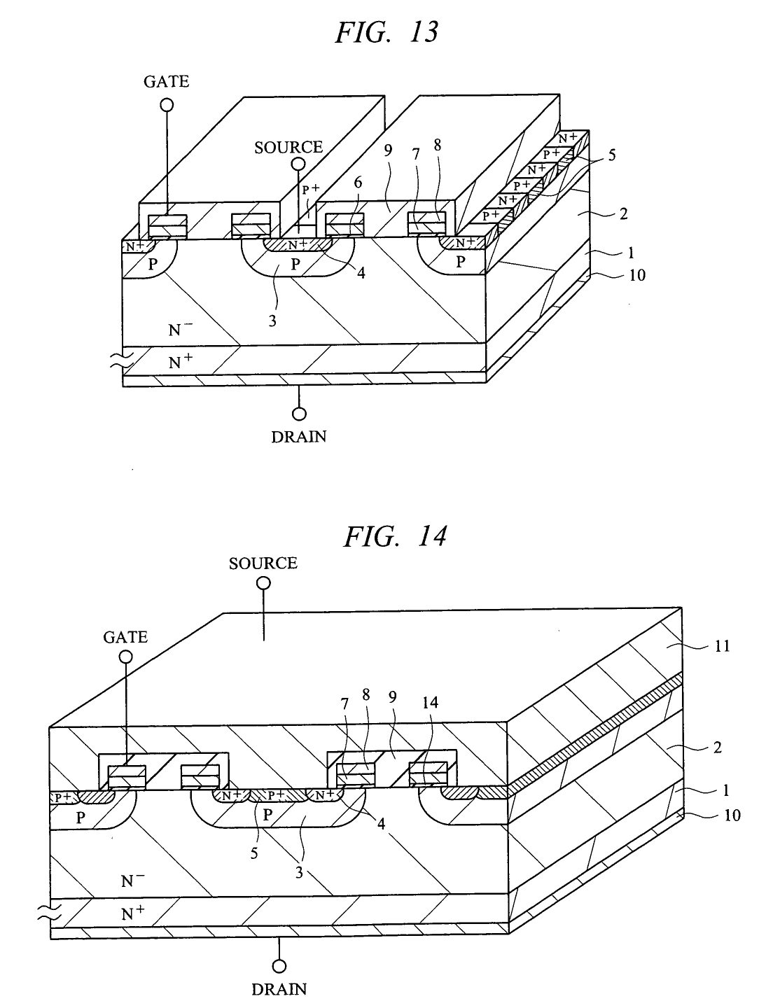

The second embodiment of the present invention will be described with reference to FIG. 13. FIG. 13 is a diagram showing a cross-sectional structure of a planar type MOSFET according to the second embodiment of the present invention. The feature of FIG. 13 lies in that the N⁺ source region 4 and the body contact region 5 are alternatively arranged in a direction vertical to the gate. In such an arrangement, the cell pitch can be reduced without changing the dimensions of the JFET region and the ON-resistance can be reduced.

### Third Embodiment

The third embodiment of the present invention will be described with reference to FIG. 14. FIG. 14 is a diagram showing a cross-sectional structure of a planar type MOSFET according to the third embodiment of the present invention. The feature of FIG. 14 lies in that an oxynitride film 14 is used for the gate insulating film. In the third embodiment, the P type polysilicon 7 is used for the gate electrode and boron (B) is used as an impurity thereof. It is known that the problem of the boron penetration occurs in the case of using an oxide film which is a normal gate insulating film. More specifically, when the thermal diffusion is performed at high temperature after the deposition of the P type polysilicon, boron in the P type polysilicon penetrates through the oxide film and reaches the semiconductor substrate. When the boron penetration occurs, the threshold voltage of the MOSFET becomes unstable.

It is known that the boron penetration described above can be prevented by the use of the oxynitride film 14 obtained by introducing nitrogen into an oxide film through the thermal oxidation in the atmosphere of gases such as nitrous oxide (N₂O), nitric oxide (NO), and ammonium (NH₃).

Since the P type polysilicon 7 containing boron is used for the gate electrode in this embodiment, there is the possibility that the problem of the boron penetration occurs. Therefore, the feature of the third embodiment lies in that the oxynitride film 14 is used for at least a part of the gate insulating film to prevent the boron penetration.

### Fourth Embodiment

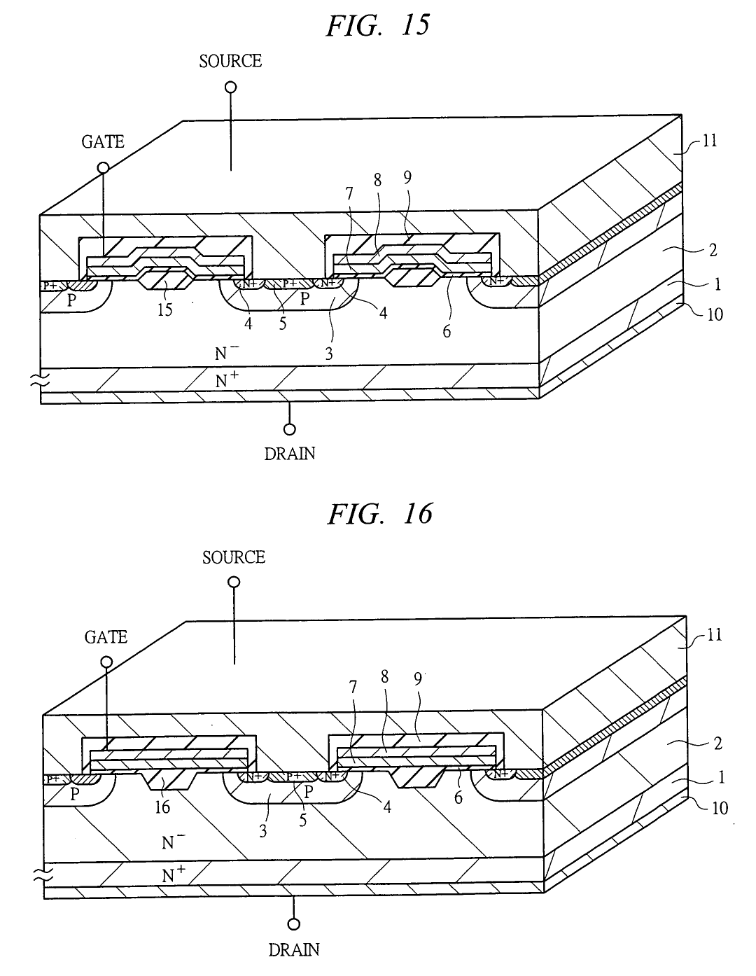

The fourth embodiment of the present invention will be described with reference to FIG. 15 and FIG. 16. FIG. 15 and FIG. 16 are diagrams showing a cross-sectional structure of a planar type MOSFET according to the fourth embodiment of the present invention. The feature of this embodiment lies in that a part of the gate insulating film opposite to the JFET region is designed to have a thickness larger than that of a part of the gate insulating film opposite to the P channel layer 3. By increasing the thickness of a part of the gate insulating film, the effect of reducing the feedback capacitance between gate and drain can be achieved.

FIG. 15 and FIG. 16 are different from each other in the method for forming the thick gate insulating film. In the case of FIG. 15, an insulating film of a LOCOS (Local Oxidization of Silicon) oxide film 15 is formed through the LOCOS process, and in the case of FIG. 16, an insulating film of an STI (Shallow Trench Isolation) oxide film 16 is formed through the STI process. Both of the processes can be performed before the gate oxidation process shown in FIG. 8B. Although it is difficult to fabricate a miniaturized thick film structure in the LOCOS process because a nitride film is first formed by using a mask and then an oxide film is formed through the thermal oxidation, the miniaturized thick film structure can be fabricated in the STI process because it is fabricated by filling an oxide film into miniaturized trenches.

Since the length of the JFET region is as short as about 0.5 μm in this embodiment, the STI process is preferably used. Since the STI process is generally used in the CMOS process with a design rule of 0.25 μm or less and the planar type MOSFET according to this embodiment can be fabricated through the CMOSFET process as shown in FIG. 8 to FIG. 12, there is no problem to use the STI process.

### Fifth Embodiment

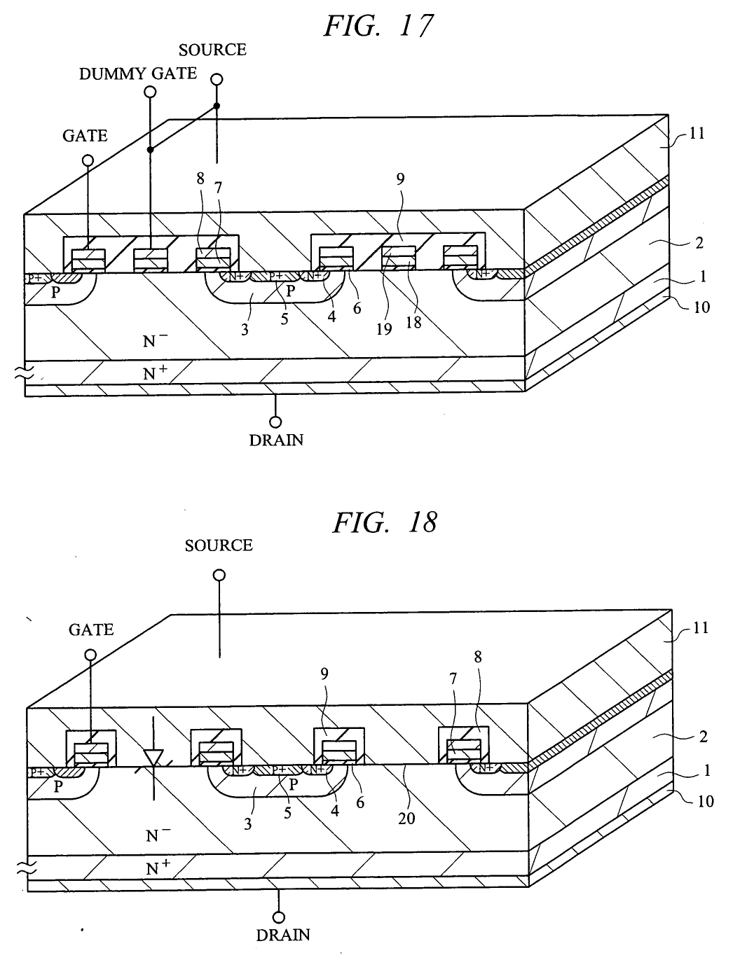

The fifth embodiment of the present invention will be described with reference to FIG. 17. FIG. 17 is a diagram showing a cross-sectional structure of a planar type MOSFET according to the fifth embodiment of the present invention. The feature of this embodiment lies in that a dummy gate electrode is provided at a position of a part opposite to the JFET region. The dummy gate electrode is connected to a source electrode, and the depletion layer expands also from the dummy gate electrode when a device is reversely biased. Therefore, the effect of further reducing the capacitance between gate and drain can be achieved.

The dummy gate electrode described above can be formed by leaving a part of a P type polysilicon 18 and a tungsten silicide film 19 of the region opposite to the JFET region in the step for the gate electrode shown in FIG. 9E, and it can be formed without adding any new steps to the process of the first embodiment.

### Sixth Embodiment

The sixth embodiment of the present invention will be described with reference to FIG. 18. FIG. 18 is a diagram showing a cross-sectional structure of a planar type MOSFET according to the sixth embodiment of the present invention. The feature of this embodiment lies in that a Schottky junction 20 is provided for a part of the JFET region. Since the Schottky junction 20 is provided for a part of the JFET region, the depletion layer expands from the Schottky junction 20 into the JFET region, and the effect of further reducing the capacitance between gate and drain can be achieved.

Also, since a Schottky barrier diode by the Schottky junction 20 is incorporated, the effect of reducing the conduction loss and the recovery loss of the diode in the dead time can be achieved particularly by using it as a low-side switch of the DC/DC converter.

### Seventh Embodiment

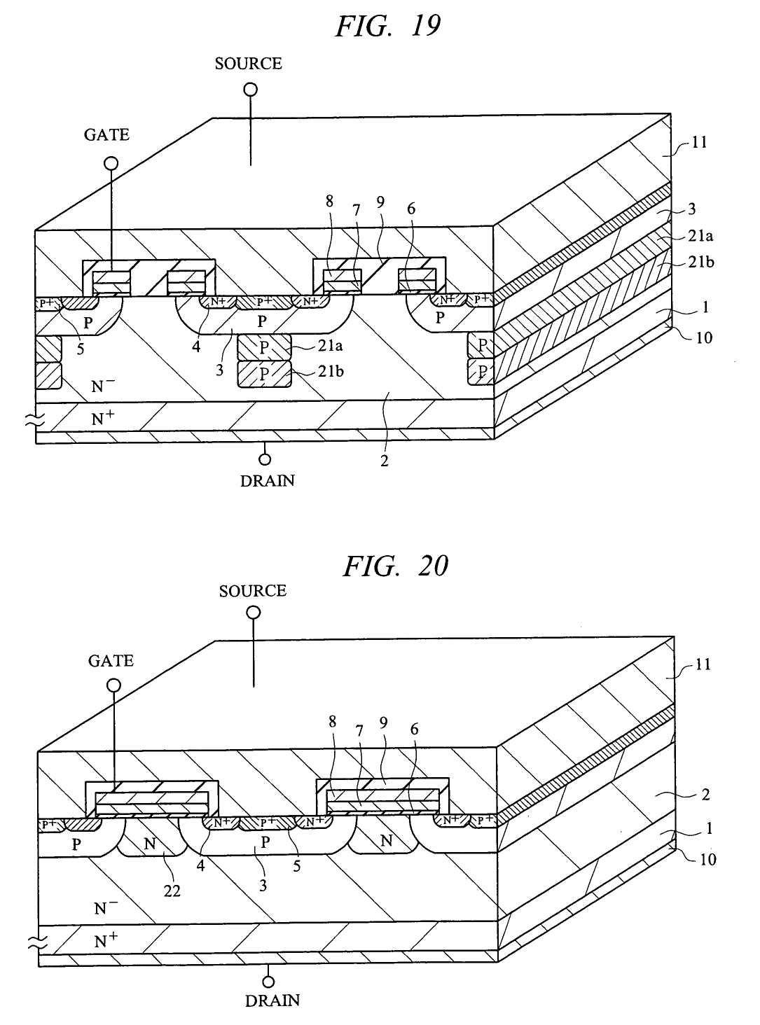

The seventh embodiment of the present invention will be described with reference to FIG. 19. FIG. 19 is a diagram showing a cross-sectional structure of a planar type MOSFET according to the seventh embodiment of the present invention. The feature of this embodiment lies in that a planar type MOSFET with a super junction structure is provided by fabricating P type regions 21a and 21b in the N⁻ epitaxial layer 2. By adopting the super junction structure, the effect of further reducing the ON-resistance of the MOSFET can be achieved.

The P type regions 21a and 21b can be fabricated by the ion implantation of boron with high energy at the step of the contact etching and implantation shown in FIG. 11L in the manufacturing method described in the first embodiment. Note that this embodiment shows an example where the P type regions 21a and 21b are formed by performing the ion implantation twice. Alternatively, it is also possible to form the P type regions 21a and 21b by performing the ion implantation once or many times.

### Eighth Embodiment

The eighth embodiment of the present invention will be described with reference to FIG. 20. FIG. 20 is a diagram showing a cross-sectional structure of a planar type MOSFET according to the eighth embodiment of the present invention. The feature of this embodiment lies in that N type regions 22 with a concentration higher than that of the N⁻ epitaxial layer 2 are formed between the P channel layers 3. By inserting the N type region 22 which is a high concentration layer, it is possible to further reduce the ON-resistance of the MOSFET.

The structure in the example where the N type region 22 is inserted is similar to that described in the Patent Document 1. In this embodiment, however, since the P type polysilicon 7 is used for the gate electrode, the impurity concentration of the N type region 22 can be further increased. More specifically, since the P type polysilicon 7 is used, the surface of the N type region 22 is depleted. Therefore, even when the impurity concentration of the N type region 22 is increased to be higher than that of the case of using the N type polysilicon, the N type region 22 can be depleted, and the decrease of the withstand voltage can be suppressed. The N type region 22 can be formed by performing the ion implantation to the entire device surface before forming the gate insulating film 6.

### Ninth Embodiment

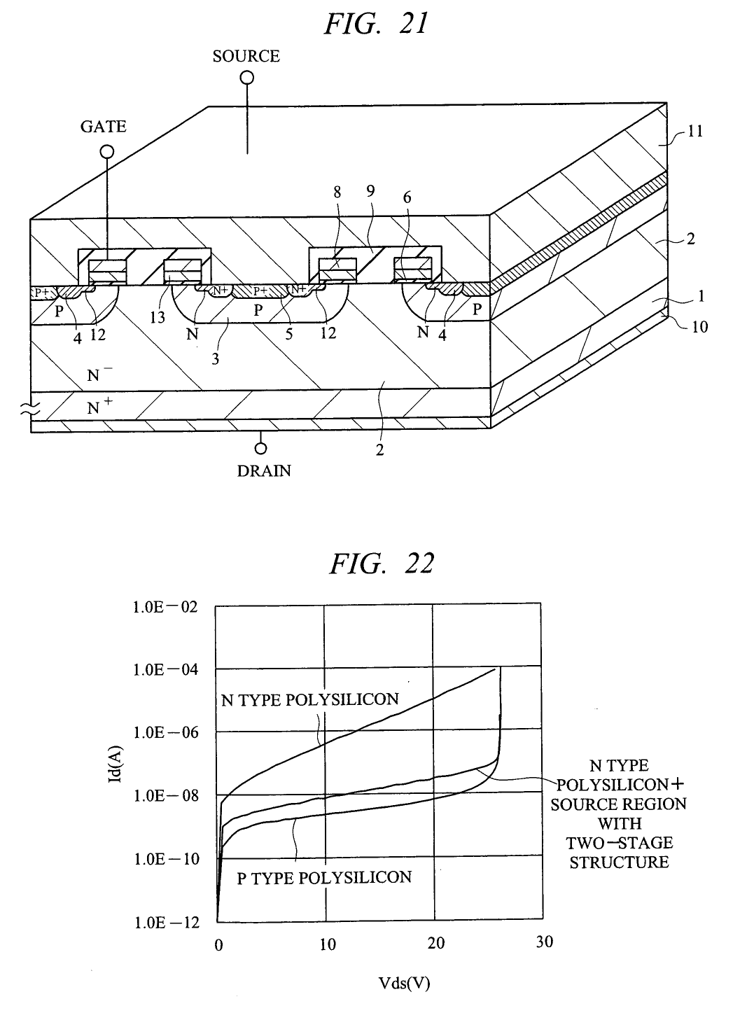

The ninth embodiment of the present invention will be described with reference to FIG. 21 to FIG. 23. FIG. 21 is a diagram showing a cross-sectional structure of a planar type MOSFET according to the ninth embodiment of the present invention. The feature of the embodiments described above lies in that the P type polysilicon 7 is used for the gate electrode to prevent the punch through of the P channel layer 3. However, the feature of this embodiment lies in that, while using the N type polysilicon 13 for the gate electrode, a shallow N type layer 12 is provided in the N⁺ source region 4 to form a two-stage structure of the N⁺ source region 4 as shown in FIG. 21, thereby preventing the punch through.

FIG. 22 is a graph showing the calculation result of the withstand voltage between drain and source in each structure. Although the leakage current is slightly increased compared with the case of using the P type polysilicon 7, the punch through can be prevented and the sharp withstand voltage curve can be obtained by forming the two-stage structure of the N⁺ source region 4 even when the N type polysilicon 13 is used for the gate electrode.

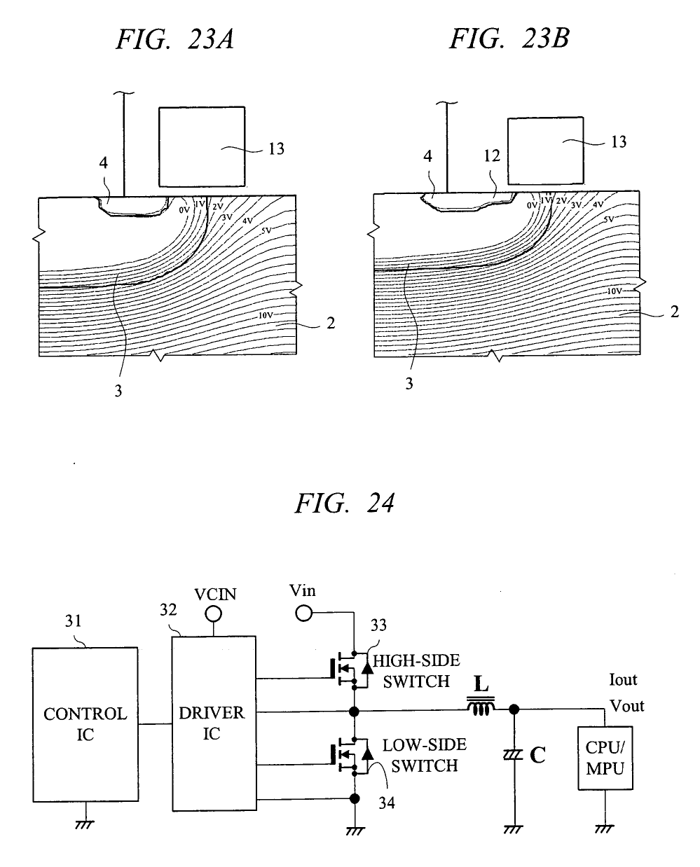

FIG. 23A and FIG. 23B are diagrams showing the two-dimensional distribution of equipotential lines at the time when the voltage of 20 V is applied between drain and source in the conventional planar type MOSFET and the planar type MOSFET according to this embodiment. As shown in FIG. 23A, the equipotential lines extend to the N⁺ source region 4 in the conventional structure. On the other hand, when the N⁺ source region 4 is designed to have the two-stage structure as shown in FIG. 23B, the equipotential lines do not reach the N⁺ source region 4, and the punch through can be prevented.

The shallow N type layer 12 according to this embodiment can be fabricated through the same process as the fabrication process of an LDD (Lightly Doped Drain) region used in the CMOS process. Since the planar type MOSFET according to this embodiment can be fabricated by the diversion of the CMOS process similar to the manufacturing method shown in FIG. 8 to FIG. 12, there is no problem to form the LDD region.

Also, the structure according to this embodiment can be applied to the example described in the second embodiment where the source region and the body contact region are alternatively arranged, the example described in the fourth embodiment where a part of the gate insulating film opposite to the JFET region is thickened, the example described in the fifth embodiment where the dummy gate electrode is used, the example described in the sixth embodiment where the Schottky junction is used, and the example described in the seventh embodiment where the super junction structure is used.

### Tenth Embodiment

In the tenth embodiment of the present invention, the planar type MOSFET described above is applied for use in a power supply device including a DC/DC converter, and the effect in this case will be described.

The tenth embodiment of the present invention will be described with reference to FIG. 24 to FIG. 26. FIG. 24 is a diagram showing a circuit configuration of the non-insulated DC/DC converter included in the power supply device. The non-insulated DC/DC converter comprises: a control IC 31; a driver IC 32; a high-side switch 33; a low-side switch 34; a smoothing inductor L; a smoothing condenser C; and others, and it is connected to CPU/MPU.

As described above, the main loss in the high-side switch 33 is the switching loss, and the reduction of the capacitance between gate and drain (Crss) is important for the reduction of the loss. Also, the reduction of the conduction loss and the loss due to the self turn-on is important in the low-side switch 34, and it is important to reduce the ON-resistance and Crss/Ciss. For its achievement, in the planar type MOSFET according to the present invention, the ON-resistance is reduced by the reduction of the cell size and the reduction of Crss can be achieved by using the planar type structure.

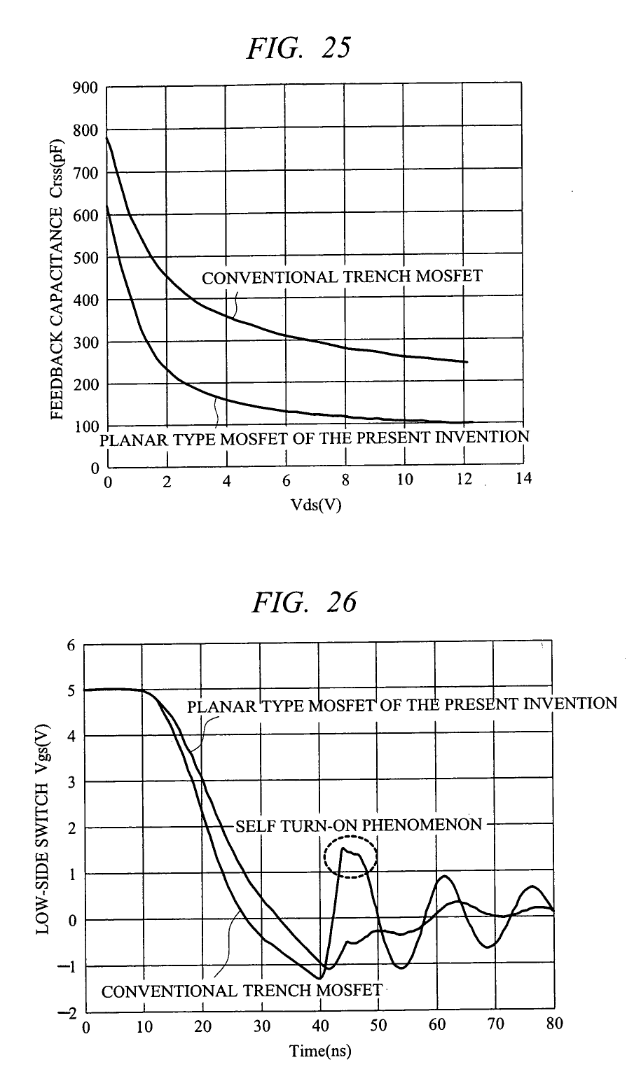

FIG. 25 is a graph showing the calculation results of the dependence of the feedback capacitance on the drain voltage in the conventional trench MOSFET and the planar type MOSFET of the present invention. It can be understood that the feedback capacitance can be decreased by using the planar type structure. Therefore, when this structure is used for the high-side switch 33 of the DC/DC converter, the switching loss can be reduced.

FIG. 26 is a graph showing the calculation results of the gate voltage of the low-side switch in the case where the conventional trench MOSFET is used for the low-side switch of the DC/DC converter and the case where the planar type MOSFET of the present invention is used for the low-side switch of the DC/DC converter. As is apparent from FIG. 26, in the conventional trench MOSFET, the self turn-on phenomenon occurs, in which the gate voltage rises to about 1.5 V. On the other hand, in the case where the planar type MOSFET of the present invention is used, since Crss/Ciss can be reduced, the gate voltage does not rise and the self turn-on phenomenon does not occur. Accordingly, when the planar type MOSFET according to the present invention is used for the low-side switch 34, the loss due to the self turn-on does not occurs and the loss can be reduced.

In the foregoing, the invention made by the inventors of the present invention has been concretely described based on the embodiments. However, it is needless to say that the present invention is not limited to the foregoing embodiments and various modifications and alterations can be made within the scope of the present invention. For example, the shallow junction of the channel layer can be applied also to the P channel planar type MOSFET, the trench type MOSFET, and the lateral MOSFET.

The present invention relates to a power MOSFET. More particularly, it can be effectively applied to a structure and its manufacturing method suitable for achieving low ON-resistance and low feedback capacitance in a low withstand voltage power MOSFET with the withstand voltage of 100 V or lower and a power supply device using the power MOSFET.

What is claimed is:

1. An N channel DMOSFET, comprising:
a gate electrode,
wherein said gate electrode is formed of a P type polysilicon electrode.

2. The DMOSFET according to claim 1,
wherein said DMOSFET is a planar type MOSFET.

3. The DMOSFET according to claim 2,
wherein a junction depth of a P channel layer of said planar type MOSFET in a longitudinal direction is 0.5 μm or less.

4. The DMOSFET according to claim 3,
wherein said P channel layer is formed by ion implantation in a direction vertical to a semiconductor substrate and thermal diffusion.

5. The DMOSFET according to claim 2,
wherein a part of said gate electrode opposite to a JFET region is removed.

6. The DMOSFET according to claim 2,
wherein said gate electrode of said planar type MOSFET has a metal electrode provided on said P type polysilicon electrode.

7. The DMOSFET according to claim 6,
wherein said metal electrode is a tungsten silicide film.

8. The DMOSFET according to claim 2,
wherein a source region and a body contact region of said planar type MOSFET are alternatively arranged in a direction vertical to said gate electrode.

9. The DMOSFET according to claim 2,
wherein at least a part of a gate insulating film between said gate electrode and a channel layer of said planar type MOSFET is formed of an oxynitride film made of an oxide film containing nitrogen.

10. The DMOSFET according to claim 2,
wherein a part of a gate insulating film opposite to a JFET region of said planar type MOSFET has a thickness larger than a part of the gate insulating film opposite to a channel layer.

11. The DMOSFET according to claim 2,
wherein a part of a region opposite to a JFET region of said planar type MOSFET has a dummy gate electrode with the same potential as a source potential provided via a gate insulating film.

12. The DMOSFET according to claim 2,
wherein a Schottky junction is provided in a part of a JFET region of said planar type MOSFET.

13. The DMOSFET according to claim 2,
wherein a P type region for depleting an N type epitaxial layer is formed in said N type epitaxial layer of said planar type MOSFET.

14. The DMOSFET according to claim 2,
wherein an N type region with a concentration higher than that of an N type epitaxial layer is formed between P channel layers of said planar type MOSFET.

15. The DMOSFET according to claim 2,
wherein said planar type MOSFET is fabricated through a CMOSFET process with a design rule of 0.25 μm or less.

16. The DMOSFET according to claim 2, applied to a power supply device including a DC/DC converter,
wherein said DMOSFET is used as a high-side switch or a low-side switch of said DC/DC converter.

17. A planar type MOSFET,
wherein a junction depth of a part of a source region close to a gate electrode is smaller than that of other part of the source region.

18. The planar type MOSFET according to claim 17,
wherein said planar type MOSFET is fabricated through a CMOSFET process with a design rule of 0.25 μm or less.

19. The planar type MOSFET according to claim 17, applied to a power supply device including a DC/DC converter,
wherein said planar type MOSFET is used as a high-side switch or a low-side switch of said DC/DC converter.
